(19) United States
(12) Patent Application Publication
(10) Pub. No.: US 2006/0268724 A1
(43) Pub. Date: Nov. 30, 2006

(54) Using Open Vera Assertions to verify designs

(76) Inventors: Ravindra Viswanath, Milpitas, CA (US); Rajinder Cheema, Milpitas, CA (US); Harish Bharadwaj, Milpitas, CA (US)

Correspondence Address: LSI LOGIC CORPORATION, 1621 BARBER LANE, MS: D-106, MILPITAS, CA, 95035, US

(21) Appl. No.: 11/136,234

(22) Filed: May 24, 2005

(51) Int. Cl. G01R 31/08

(52) U.S. Cl. 370/242; 370/389

(57) ABSTRACT

A method for verifying a protocol employed by a protocol handler. In an embodiment, the method includes verifying a Receive Link Layer defined within a protocol handler with Open Vera Assertions. The Receive Link Layer may include a plurality of interfaces and is configured for separating data into a series of packets. Further, a plurality of features included within the series of packets are monitored with Open Vera Assertions. Additionally, functional coverage is measured with coverage statements based upon Open Vera Assertions. Finally, Open Vera Assertion severity and error isolation is controlled through message logging.

### FIELD OF THE INVENTION

The present invention relates generally to the field of integrated circuits and more particularly to verification of protocol handlers such as peripheral component interconnect (PCI) Express using Open Vera Assertions (OVA).

### BACKGROUND OF THE INVENTION

Over the last decade, peripheral component interconnect (PCI) has been employed ubiquitously in communications and embedded applications as a local interconnect technology. Current communications and embedded applications, however, require higher bandwidths which pose a serious challenge to the parallel bus architecture employed by PCI. In order to accommodate the higher bandwidths, PCI Express (technology formerly known as Third Generation I/O, 3GIO) has been developed which replaces the parallel bus architecture that required the devices within the system to share a bus with a point-to-point bus topology which shares a switch instead of a bus. Unlike the shared bus topology where the devices must collectively arbitrate amongst themselves for use of the bus, the PCI Express environment provides each device with direct and exclusive access to the switch. Thus, PCI Express is a general purpose interconnect technology that is defined for various products presently available as well as possibly for future computing and communication platforms.

The complex serial protocols employed by PCI Express for accommodating communications and embedded applications with higher bandwidths have required the development of specialized approaches which verify compliance with such complex protocol standards. Typically, verification of protocol handlers such as PCI requires a dedicated environment with transactors and bus functional models (BFM) modeled to reflect the protocol and each interface of the device under test (DUT). Such configuration translates into separate efforts being spent on the design and the verification environment which results in inefficiency.

Further, PCI Express employs an interface which has extensive protocol definitions that require a number of monitors to track the definitions during simulation. In general, such monitors are written in verilog. The use of verilog is disadvantageous for systems with complex, extensive protocol definitions for a variety of reasons. First, verilog has been demonstrated to be very verbose when describing complex protocols that extend over time or are even impossible to describe. Further, the procedural nature of the verilog language also leaves the possibility of missing events. For instance, as the number of checks increases, the ability to manage verilog becomes increasingly difficult. Additionally, verilog does not include a mechanism to provide coverage information on the monitors and thus, requires the user to create this part of the code.

Therefore, it would be desirable to provide a verification method for protocol handlers such as PCI Express cores which does not require a dedicated environment to reflect the protocol and each interface of the DUT. Further, it would be desirable for such method to be written in a language which may be controlled over an extended period of time and include built-in coverage mechanisms.

### SUMMARY OF THE INVENTION

Accordingly, the present invention is directed to a method for verifying a protocol employed by a protocol handler. In an aspect of the present invention, the method includes verifying a Receive Link Layer defined within a protocol handler with Open Vera Assertions. The Receive Link Layer may include a plurality of interfaces and is configured for separating data into a series of packets. Further, a plurality of features included within the series of packets are monitored with Open Vera Assertions. Additionally, functional coverage is measured with coverage statements based upon Open Vera Assertions. Finally, Open Vera Assertion severity and error isolation is controlled through message logging.

In such aspect, the protocol handler includes serial interconnect technology. For example, the protocol handler includes 8 (eight) individual serial lanes for transmitting and receiving data. Further, in the present aspect, a Receive Link Layer is defined within the protocol handler for separating data into a series of packets. The Receive Link Layer may include a plurality of interfaces such as a Receive Physical Layer interface, a Transmit Link Layer Interface, and a Receive Transaction Layer Interface. Moreover, the series of packets may include transaction layer packets and data link layer packets. Additionally, in the instant aspect, a plurality of checkers are coupled to the plurality of interfaces for checking the data included within the series of packets generated by the Receive Link Layer. For instance, the plurality of checkers include a transaction layer packet checker, a data link layer packet checker, and a cyclic redundancy checker. Furthermore, a mechanism is defined within the protocol handler for providing coverage information on the plurality of checkers so that the plurality of checkers and the mechanism for providing coverage information on such checkers are based upon Open Vera Assertion language.

In further aspects of the present invention, the transaction layer packets are monitored for at least one of cyclic redundancy, sequence number, bad termination, invalid transmission, sequence duplication, and size of packet. Further, the data link layer packets are monitored for at least one of cyclic redundancy, sequence number, bad termination, and physical layer error. Additionally, functional coverage includes test plan coverage and protocol coverage. For example, test plan coverage provides information on the amount that a test plan is covered by a verification environment whereas protocol coverage provides behavioral information on a device under test.

In an additional aspect of the present invention, an additional method for verifying a PCI Express Protocol including the use of Open Vera Assertions is provided. First, a protocol handler is configured to function as a local interconnect. In an aspect of the present invention, the protocol handler is a PCI Express protocol handler and includes serial interconnect technology. Further, a Receive Link Layer is defined within the protocol handler for separating data into a series of packets. Such Receive Link Layer may include a plurality of interfaces. For example, the plurality of interfaces include a Receive Physical Layer interface, a Transmit Link Layer Interface, and a Receive Transaction Layer Interface. Additionally, the series of packets include transaction layer packets and data link layer packets. Furthermore, a plurality of checkers are coupled to the plurality of interfaces for checking the data included within the series of packets generated by the Receive Link Layer. Finally, a mechanism is defined within the protocol handler for providing coverage information on the plurality of checkers so that the plurality of checkers and the mechanism for providing coverage information on such checkers are based upon Open Vera Assertion language.

It is to be understood that both the forgoing general description and the following detailed description are exemplary and explanatory only and are not restrictive of the invention as claimed. The accompanying drawings, which are incorporated in and constitute a part of the specification, illustrate an embodiment of the invention and together with the general description, serve to explain the principles of the invention.

### BRIEF DESCRIPTION OF THE DRAWINGS

The numerous advantages of the present invention may be better understood by those skilled in the art by reference to the accompanying figures in which:

FIG. 1 is a block diagram of a device under test in accordance with the present invention, wherein a Receive Link Layer of a PCI Express protocol handler includes three interfaces;

FIG. 2 is an exemplary OVA code for valid and invalid Starts check;

FIG. 3 is an exemplary OVA code for cyclic redundancy checking (CRC) error check;

FIG. 4 is an exemplary OVA code for Data Link Layer Packets (DLLP) length check;

FIG. 5 is an exemplary OVA code for Transaction Layer delimit check;

FIG. 6 is an exemplary OVA code for collecting functional coverage data;

FIG. 7 is a flow diagram demonstrating a method of verifying a PCI Express Protocol in accordance with the present invention, wherein the method is based upon OVA language; and

FIG. 8 is a flow diagram demonstrating an additional method of verifying a PCI Express Protocol in accordance with the present invention, wherein the method is based upon OVA language.

### DETAILED DESCRIPTION OF THE INVENTION

Reference will now be made in detail to the presently preferred embodiments of the invention, examples of which are illustrated in the accompanying drawings. It is to be appreciated that corresponding reference numbers refer to generally corresponding structures.

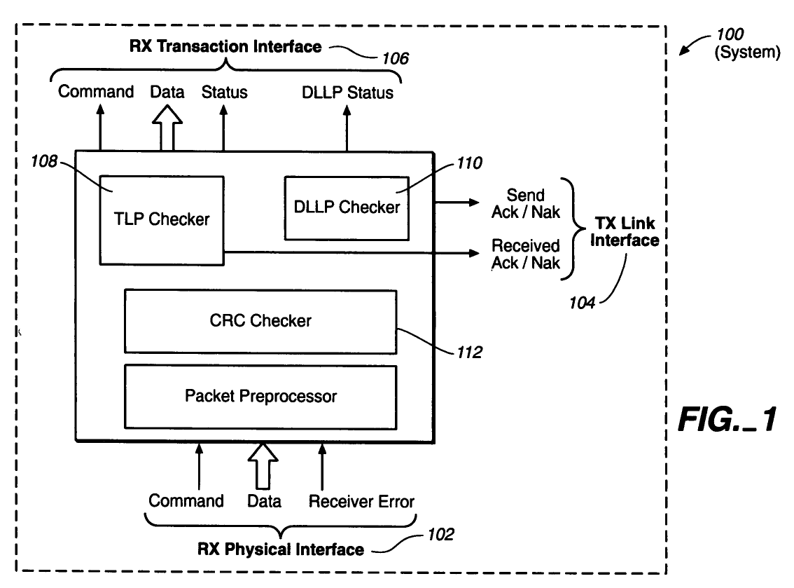

Referring now specifically to FIG. 1, an exemplary device under test (DUT) is provided which includes a system 100 including various protocol monitors/checkers based upon OVA language for verifying PCI protocol handler. As illustrated in FIG. 1, the system 100 includes a Receive Link Layer of a PCI Express protocol handler with three interfaces: the Receive Physical Layer interface 102, the Transmit Link Layer interface 104, and the Receive Transaction Layer interface 106. The Receive Link Layer separates data into various packets. For example, the data may be separated into Transaction Layer Packets (TLP) which are forwarded to the Receive Transaction Layer interface 106 after performing some checks and Data Link Layer Packets (DLLP) which are decoded and processed after due checks.

In an embodiment, the TLP are checked for cyclic redundancy, sequence number, bad termination, invalid transmission, sequence duplication, and size of the packet. In such embodiment, upon completion of the checks the packet is forwarded to the Transaction layer with the Data Link layer headers stripped, but with the status of the said checks for the packet, and the presence and position of Starts and Ends to form the Transaction Layer interface 106.

In an additional embodiment, the DLLP are checked for cyclic redundancy, sequence number, bad termination, and physical layer errors. If no errors are found, such packets are decoded. In such embodiment, the DLLP may include multiple types of packets including packets for Flow Control, Power Management, and Transaction Layer Packet processing. For example, the DLLP may include 9 (nine) types of Flow Control packets, 4 (four) types of Power Management packets, and 2 (two) types of Transaction Layer processing packets. In such example, the Flow Control and Power Management information is forwarded on to the Transaction Layer following the detection of no errors and decoding. If TLP are received without error an acknowledgement message of such finding (such as ACK DLLP) is transmitted. However, if errors are found, an alternative message such as NAK (negative acknowledgement) DLLP is transmitted. Such transmission may occur from a “Retry Buffer” present in the Transmit Link. Consequently, when either acknowledgement is received, indication of receipt is sent out to the Transmit Link Layer Interface 104 to either purge or retransmit from the Retry Buffer.

In an embodiment, the TLP include 8 (eight) bytes of Data Link headers—1 (one) byte Start indicator, 2 (two) bytes sequence number, 4 (four) bytes of cyclic redundancy checking (CRC) and 1 (one) byte termination indicator. Further, in such embodiment, DLLP include 4 (four) bytes of Data Link headers—1 byte Start indicator, 2 byte CRC indicator, and 1 byte termination indicator.

In an embodiment, the PCI Express protocol handler includes 8 (eight) individual serial lanes for transmitting and receiving data. It is contemplated that the number of individual serial lanes may vary according to user need including 4 (four) individual serial lanes or 1 (one) individual serial lane. In the present embodiment, the Receive Physical Layer interface 102 is the input interface. Such interface 102 provides 8 bits of data per lane, and a “command” indicating the presence and position of Start and Termination characters in the data stream. Further, in such embodiment, TLP and DLLP have lengths in multiples of 4 (four). For example, in an embodiment, the DLLP are exactly 8 bytes in length, while the TLP have variable lengths.

Additionally, the Starts and Ends present within the PCI Express protocol handler may occur in different lanes. For instance, Starts may occur on Lanes 0 (zero) or 4 (four) while Ends occur on Lanes 3 (three) or 7 (seven). Moreover, in an embodiment, Starts are of two types corresponding to the two types of packets that flow on the link. For example, STP Starts represent Starts for Transaction Layer packets and SDP Starts for Data link Layer packets Starts. Further, in such embodiment, two types of Ends may occur (e.g. END for a “good” termination and EDB for a “bad” termination).

As described previously, PCI Express employs an interface which has extensive protocol definitions that require a number of monitors to track the definitions during simulation. See FIG. 1. In the present disclosure, checkers for the three distinct interfaces present in the Receive Link Layer (e.g. Receive Transaction Layer Interface 106, Transmit Link Layer Interface 104, and Receive Physical Layer Interface 102) are provided.

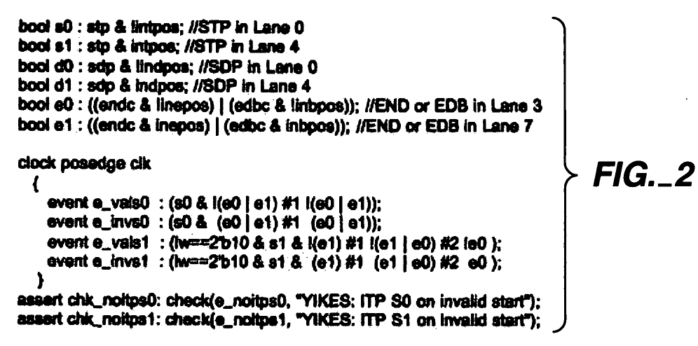

In an exemplary embodiment, a TLP Checker 108 is present to check the TLPs, a DLLP Checker 110 for the DLLPs, and a CRC Checker 112 for the CRCs. For example, for TLP to be reported to the Transaction Layer interface 106, such TLP is longer than 8 (eight) bytes inclusive of the Data Link Layer headers. Such configuration is a result of the Data Link Layer headers being 8 (eight) bytes in length. Thus, in such embodiment, an STP is valid only if an End (END or EDB) does not appear within 8 (eight) bytes from the Start. Therefore, in the present embodiment, if a TLP is 8 (eight) bytes or less in length, it would not appear on the Transaction Layer interface 106. In contrast, if the TLP is greater than 8 (eight) bytes it would appear on such interface 106. If a TLP is greater than 8 (eight) bytes long and ends in an EDB, an “EDB Received Error” is displayed on the Transaction Layer Interface 106. An exemplary OVA code for Valid and Invalid Starts check is provided in FIG. 2.

In further exemplary embodiments, if a TLP is more than 8 (eight) bytes in length and the terminator was accompanied by a Receiver Error, such status is indicated as a “Receiver Error” on the Transaction Layer Interface 106. Additionally, if a received TLP is more than 8 (eight) bytes in length and does not pass the sequence check, such finding is indicated as a “Sequence Number Error” on the Transaction Layer Interface 106. Moreover, in an embodiment, if a received TLP is more than 8 (eight) bytes long and has a duplicate sequence number (as defined in the protocol), the status indicates a “Sequence Duplication Error” on the Transaction Layer interface 106.

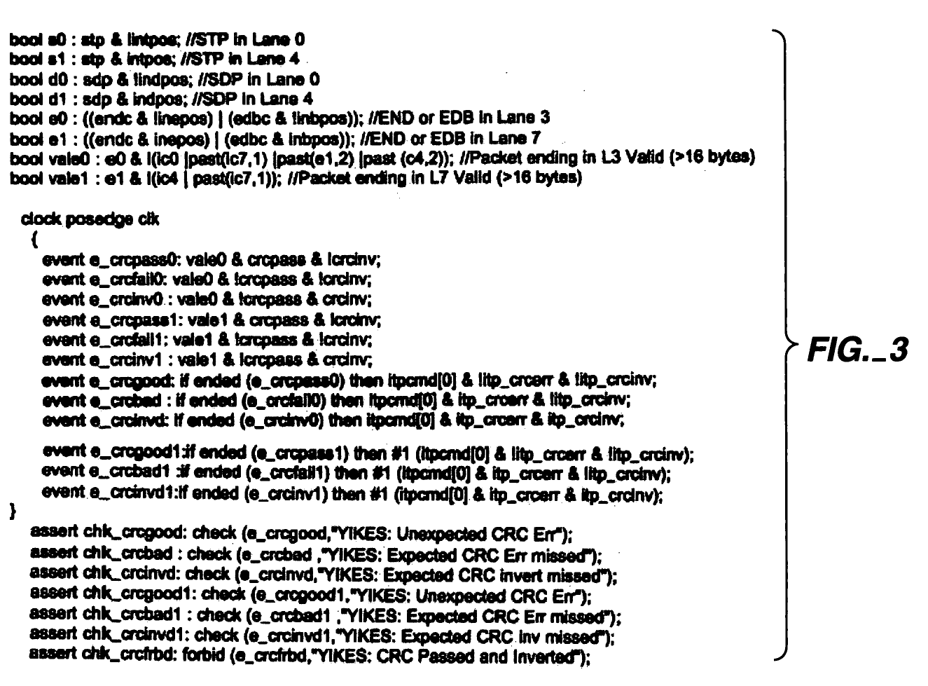

Referring to FIG. 3, exemplary OVA code for CRC error check of a TLP is provided. In exemplary embodiments, if a received TLP is more than 8 (eight) bytes in length and the CRC within the TLP does not match the CRC calculated over the TLP, the status indicates a “CRC Error” on the Transaction Layer interface 106. Additionally, if a received TLP is more than 8 (eight) bytes in length and the CRC within the TLP is an exact inversion of the CRC calculated over the TLP, the status indicates “CRC Inverted Error” on the Transaction Layer interface 106 (CRC inversion along with EDB received but no other errors is an invalid TLP transmit).

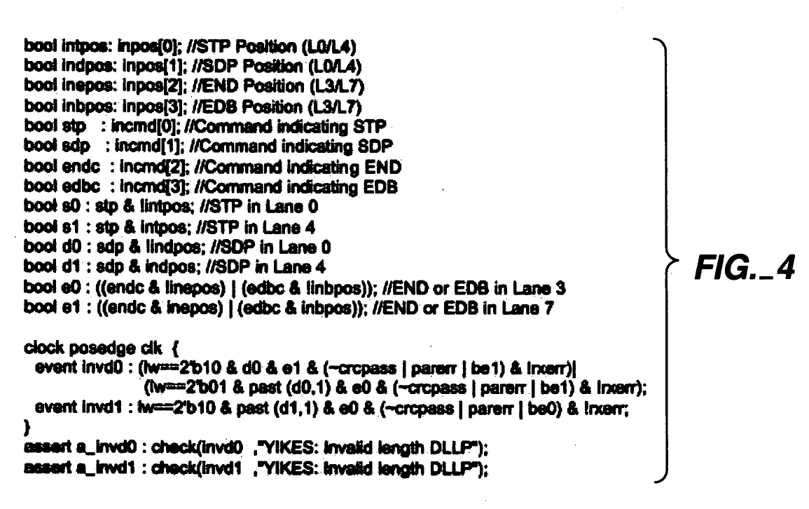

Referring to FIG. 4, an exemplary OVA code for DLLP length check is provided. In an exemplary embodiment, a “valid DLLP” for a DLLP exactly 8 (eight) bytes in length in a 8-Lane PCI Express link is defined as a DLLP with an SDP in Lane 0 (zero) and an END in Lane 7 (seven) or an SDP in Lane 4 (four) and an END in Lane 4 (four) of the following clock cycle, with no CRC error, parity error, EDB error or Receiver error accompanying it. In such embodiment, a signal indicating a “Good DLLP” is asserted for a valid DLLP. In an additional embodiment, a DLLP with the correct length however including one or more of a CRC error, parity error, EDB error or Receiver a signal indicating “Bad DLLP” is asserted and all signals indicating the decode values are reset.

As stated previously in an exemplary embodiment the DLLP include 15 (fifteen) different types of packets (e.g., 9 types for Flow Control; 4 types of Power Management; and 2 types for Transaction Layer Packet processing). Such packets may be further sub-divided. For example, Flow Control may be sub-divided into Initialization Flow Control 1, Initialization Flow Control 2, and Update Flow Control packets. In an embodiment, Flow Control 1 includes packets denoted as posted, non-posted and completion. In such embodiment, Flow Control 2 and Update Flow Control include similar packets. Additionally, in the present embodiment, Power management is divided into packets denoted as PM_Enter_L1, PM_Enter_L23, PM_Active_State_Request_L1, and PM_Request_Ack. Moreover, one of the DLLP includes ACK/NAK. In the embodiment, for each of the aforementioned types of DLLP, the respective decode signals such as sequence number for ACK/NAK DLLPs, Power management Type for Power management DLLPs, Flow Control Type, Virtual Channel, Data Credits and Header Credits for Flow Control DLLP are asserted. In further embodiments which include a DLLP of desired length (e.g. exactly 8 bytes) with no detectable errors, none of the aforementioned decode signals are asserted instead, an “Unknown DLLP type” signal is asserted and a corresponding 32 (thirty-two) byte “Unknown DLLP data” is reflected in the DLLP content. In a further embodiment, detection of a DLLP of incorrect length (e.g., a DLLP with a length not equal to 8-bytes) is not transmitted, but dropped with no indication on any decode or status signals.

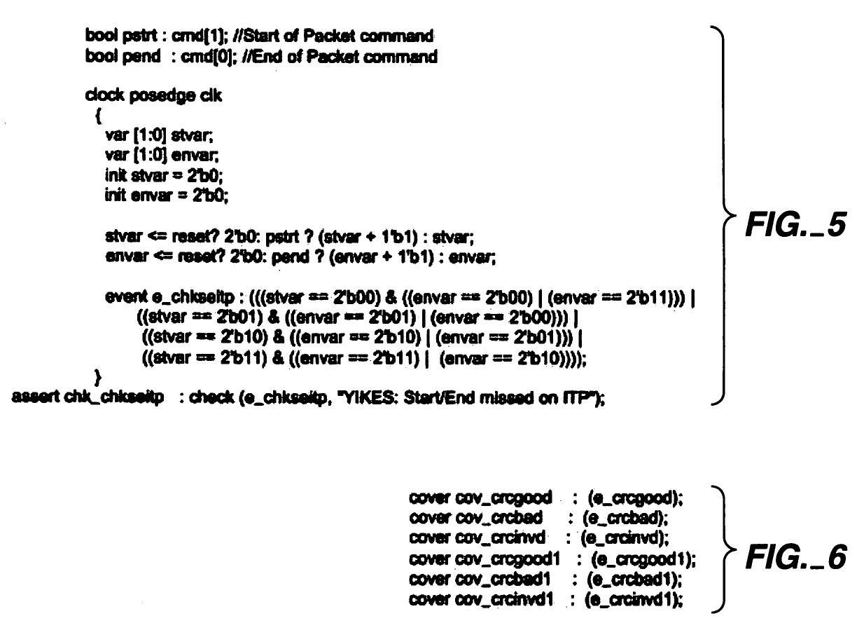

Referring to FIG. 5, an exemplary OVA code for Transaction Layer Interface 106 delimited check is provided. In an exemplary embodiment, packets which are forwarded to the Transaction Layer Interface 106 are checked to ensure correct delimitation. For example, packets are checked to make sure that an End is present in between two Starts and a Start is in between two Ends. Further, in the embodiment, the forwarding of a TLP to the Transaction Layer Interface 106 without any detected errors asserts a signal indicating “Good TLP” as well as a signal initiating the transmission of an ACK DLLP to the Transmit Link Interface 104 along with the sequence number of the packet. Moreover, in the present embodiment, the forwarding of a TLP to the Transaction Layer Interface 106 with detected errors asserts a signal indicating “Bad TLP” as well as a signal initiating the transmission of an NAK DLLP to the Transmit Link Interface 104 along with the sequence number of the last “good” packet received. It is contemplated that the signal transmission may vary depending upon the type of error and as specified by protocol handler. For example, a receiver error may not result in a NAK signal being transmitted.

Referring to FIG. 6 exemplary OVA code for collecting functional coverage data is provided. In an exemplary embodiment, the system 100 includes built in coverage mechanisms. In such embodiment, functional coverage is categorized in two sets: (1) Test Plan Coverage and (2) Protocol Coverage. First, Test Plan Coverage provides information on how much of the test plan is covered by the verification environment. For example, the test plan may require a user to verify the DUT with a minimum of 50 (fifty) different packet lengths. This kind of coverage can be obtained efficiently within the test environment. For example, in a high-level verification language like OVA, it is easy to define coverage objects that create bins and calculate this information. Protocol Coverage, on the other hand, is more close to the DUT and such information in an embodiment is extracted from the functional specification of the DUT itself. Such extraction provides information on the DUT behavior. For example, the extraction may ensure that all possible legal condition of the DUT has been exercised as well as that all illegal conditions are handled by the design as well. In an exemplary embodiment such extraction occurs employing OVA. For instance, OVA language provides a keyword “cover” that allows the user to get information on different events and assertions.

In an embodiment, coverage statements are defined for TLP and DLLP employing various protocols. Further, in such embodiment, OVA severity and error isolation is controlled through efficient message logging. For example, fatal errors may be identified by using “YIKES” in the display message of the assertion failure. In the present embodiment, coverage statements for TLP are defined for the following protocols: (1) TLP less than 8 (eight) bytes long starting on Lanes 0 and 4; (2) TLP less than 8 (eight) bytes long ending on Lanes 3 and 7; (3) Valid TLP starting/ending on lanes 0,4/3,7 with no errors; (4) Valid TLP starting/ending on lanes 0,4/3,7 with receiver errors; (5) Valid TLP starting/ending on lanes 0,4/3,7 with EDBs; (6) Valid TLP starting/ending on lanes 0,4/3,7 with sequence number errors; (7) Valid TLP starting/ending on lanes 0,4/3,7 with sequence duplication errors; (8) Valid TLP starting/ending on lanes 0,4/3,7 with CRC errors; (9) Valid TLP starting/ending on lanes 0,4/3,7 with CRC inversion errors; and (10) Sequence number rollover (e.g., sequence number count rolling over its maximum value). It is contemplated that the protocol may vary depending environmental conditions including the PCI Express protocol handler being configured with an alternative number of serial lanes such as 4 or 1 (compared to the present embodiment which includes 8).

In additional embodiments, coverage statements for DLLP are defined for the following protocols: (1) DLLP of each valid type starting/ending lanes 0,4/3,7 with no errors; (2) DLLP of each valid type starting/ending lanes 0,4/3,7 with Receiver errors; (3) DLLP of each valid type starting/ending lanes 0,4/3,7 with EDB errors; (4) DLLP of each valid type starting/ending lanes 0,4/3,7 with CRC errors; (5) DLLP of each valid type starting/ending lanes 0,4/3,7 with no errors; (6) DLLP of each valid type starting/ending lanes 0,4/3,7 with each type of error; and (7) DLLP of each valid type starting/ending lanes 0,4/3,7. It is to be understood that protocol parameters may vary depending environmental conditions including the PCI Express protocol handler being configured with an alternative number of serial lanes such as 4 or 1 (compared to the present embodiment which includes 8).

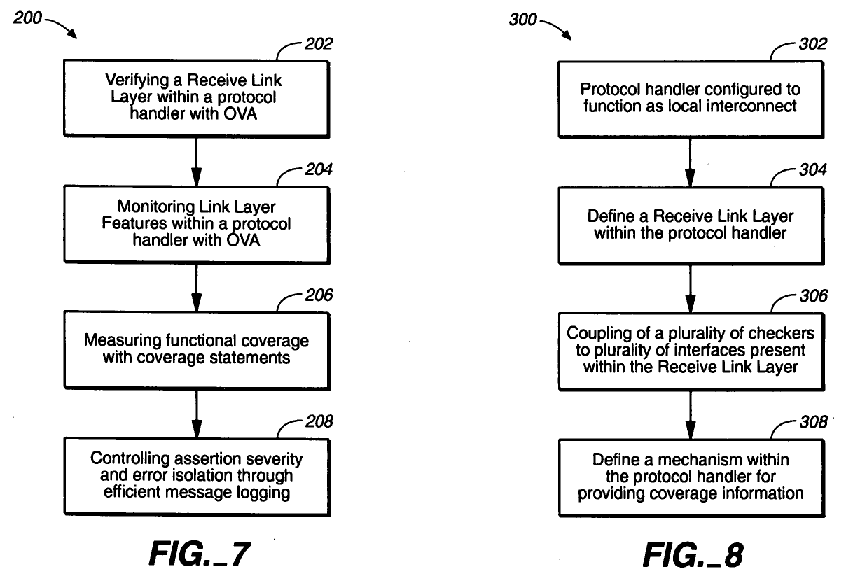

Referring to FIGS. 7 and 8, methods for verifying a protocol handler (e.g. a PCI Express Protocol handler) including the features described above are provided. As illustrated in FIG. 7, Method 200 includes Step 202 for verifying the Receive Link Layer within a protocol handler such as PCI Express with Open Vera Assertions. For example, the PCI Express Receive Link Layer is verified with Open Vera Assertions at a plurality of interfaces including the Transaction Layer Interface 106, the Transmit Link Layer Interface 104, and the Receive Physical Layer Interface 102. In a second step, 204, Link Layer Features are monitored within the protocol handler with Open Vera Assertions. For instance, the TLP may be monitored for sequence number, CRC, bad termination, invalid transmission, sequence duplication, size of packet, Physical Layer Errors, and the like. Further, in additional embodiments, the DLLP are monitored for CRC, bad termination, and Physical Layer Errors, and the like. In a third step, 206, functional coverage is measured with coverage statements based upon Open Vera Assertions. In a fourth step, assertion severity and error isolation is controlled through efficient message logging.

Referring to FIG. 8, an additional method, method 300, for verifying a protocol handler (e.g. a PCI Express Protocol handler) including the use of Open Vera Assertions is provided. First, a protocol handler is configured to function as a local interconnect, Step 302. In an embodiment of the present invention, the protocol handler is a PCI Express protocol handler and includes serial interconnect technology. For example, the protocol handler may include 8 (eight) individual serial lanes for transmitting and receiving data. Alternatively, the protocol handler may be configured with 4 (four) lanes or 1 (one) serial lane. In a second step, 304, a Receive Link Layer is defined within the protocol handler for separating data into a series of packets. Such Receive Link Layer may include a plurality of interfaces. For example, the plurality of interfaces include a Receive Physical Layer interface, a Transmit Link Layer Interface, and a Receive Transaction Layer Interface. Additionally, the series of packets include transaction layer packets and data link layer packets. In a third step, 306, a plurality of checkers are coupled to the plurality of interfaces for checking the data included within the series of packets generated by the Receive Link Layer. In a fourth step, 308, a mechanism is defined within the protocol handler for providing coverage information on the plurality of checkers so that the plurality of checkers and the mechanism for providing coverage information on such checkers are based upon Open Vera Assertion language.

Although the present disclosure focuses on a system and a method for verifying a PCI Express protocol handler including 8 (eight) individual serial lanes for transmitting and receiving data, the scope and spirit of the invention is to encompass PCI Express protocol handlers which include different numbers of lanes (e.g., one or four instead of eight). As such, the aforementioned embodiments would be altered accordingly to accommodate such variation. Additionally, it is contemplated that the instant invention may be employed to verify protocol handlers which are similar to PCI Express.

It is to be noted that the foregoing described embodiments according to the present invention may be conveniently implemented using conventional general purpose digital computers programmed according to the teachings of the present specification, as may be apparent to those skilled in the computer art. Appropriate software coding may readily be prepared by skilled programmers based on the teachings of the present disclosure, as may be apparent to those skilled in the software art.

It is to be understood that the present invention may be conveniently implemented in forms of a software package. Such a software package may be a computer program product which employs a computer-readable storage medium including stored computer code which is used to program a computer to perform the disclosed function and process of the present invention. The computer-readable medium may include, but is not limited to, any type of conventional floppy disk, optical disk, CD-ROM, magneto-optical disk, ROM, RAM, EPROM, EEPROM, magnetic or optical card, or any other suitable media for storing electronic instructions.

It is understood that the specific order or hierarchy of steps in the foregoing disclosed methods are examples of exemplary approaches. Based upon design preferences, it is understood that the specific order or hierarchy of steps in the method can be rearranged while remaining within the scope of the present invention. The accompanying method claims present elements of the various steps in a sample order, and are not meant to be limited to the specific order or hierarchy presented.

It is believed that the present invention and many of its attendant advantages will be understood by the forgoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof. It is the intention of the following claims to encompass and include such changes.

What is claimed is:

1. A method for verifying a protocol employed by a protocol handler, comprising:
verifying a Receive Link Layer defined within a protocol handler with Open Vera Assertions, the Receive Link Layer including a plurality of interfaces and configured for separating data into a series of packets;
monitoring a plurality of features included within the series of packets with Open Vera Assertions;
measuring functional coverage with coverage statements based upon Open Vera Assertions; and
controlling Open Vera Assertion severity and error isolation through message logging.

2. The method for verifying a protocol as claimed in claim 1, wherein the protocol handler is PCI Express.

3. The method for verifying a protocol as claimed in claim 1, wherein the plurality of interfaces include a Receive Physical Layer interface, a Transmit Link Layer Interface, and a Receive Transaction Layer Interface.

4. The method for verifying a protocol as claimed in claim 1, wherein the series of packets include transaction layer packets and data link layer packets.

5. The method for verifying a protocol as claimed in claim 4, wherein the transaction layer packets are monitored for at least one of cyclic redundancy, sequence number, bad termination, invalid transmission, sequence duplication, and size of packet.

6. The method for verifying a protocol as claimed in claim 4, wherein the data link layer packets are monitored for at least one of cyclic redundancy, sequence number, bad termination, and physical layer error.

7. The method for verifying a protocol as claimed in claim 1, wherein the series of packets are monitored by a plurality of checkers.

8. The method for verifying a protocol as claimed in claim 7, wherein the plurality of checkers include a transaction layer packet checker, a data link layer packet checker, and a cyclic redundancy checker.

9. The method for verifying a protocol as claimed in claim 1, wherein the protocol handler includes 8 (eight) individual serial lanes for transmitting and receiving data.

10. The method for verifying a protocol as claimed in claim 1, wherein functional coverage includes test plan coverage and protocol coverage.

11. The method for verifying a protocol as claimed in claim 10, wherein test plan coverage provides information on the amount that a test plan is covered by a verification environment.

12. The method for verifying a protocol as claimed in claim 10, wherein protocol coverage provides behavioral information on a device under test.

13. A method for verifying a protocol employed by a protocol handler, comprising:
verifying a Receive Link Layer defined within a protocol handler with Open Vera Assertions, the Receive Link Layer including a plurality of interfaces and configured for separating data into a series of packets, the protocol handler being a PCI Express protocol handler and including serial interconnect technology;
monitoring a plurality of features included within the series of packets with Open Vera Assertions, the series of packets including transaction layer packets and data link layer packets;
measuring functional coverage with coverage statements based upon Open Vera Assertions; and
controlling Open Vera Assertion severity and error isolation through message logging.

14. The method for verifying a protocol as claimed in claim 13, wherein the plurality of interfaces include a Receive Physical Layer interface, a Transmit Link Layer Interface, and a Receive Transaction Layer Interface.

15. The method for verifying a protocol as claimed in claim 13, wherein the transaction layer packets are monitored for at least one of cyclic redundancy, sequence number, bad termination, invalid transmission, sequence duplication, and size of packet.

16. The method for verifying a protocol as claimed in claim 13, wherein the data link layer packets are monitored for at least one of cyclic redundancy, sequence number, bad termination, and physical layer error.

17. The method for verifying a protocol as claimed in claim 13, wherein the series of packets are monitored by a plurality of checkers.

18. The method for verifying a protocol as claimed in claim 17, wherein the plurality of checkers include a transaction layer packet checker, a data link layer packet checker, and a cyclic redundancy checker.

19. The method for verifying a protocol as claimed in claim 1, wherein functional coverage includes test plan coverage and protocol coverage.

20. A method for verifying a PCI Express Protocol including the use of Open Vera Assertions, comprising:
configuring a protocol handler to function as a local interconnect, the protocol handler being a PCI Express protocol handler and including serial interconnect technology;
defining a Receive Link Layer within the protocol handler for separating data into a series of packets, the Receive Link Layer including a plurality of interfaces, the plurality of interfaces including a Receive Physical Layer interface, a Transmit Link Layer Interface, and a Receive Transaction Layer Interface; the series of packets including transaction layer packets and data link layer packets;
coupling a plurality of checkers to the plurality of interfaces for checking the data included within the series of packets generated by the Receive Link Layer; and
defining a mechanism within the protocol handler for providing coverage information on the plurality of checkers so that the plurality of checkers and the mechanism for providing coverage information on such checkers are based upon Open Vera Assertion language.
